(19) United States
(12) Patent Application Publication
(10) Pub. No.: US 2021/0013889 A1
(43) Pub. Date: Jan. 14, 2021

(54) SYSTEM AND METHOD FOR CORRECTING PHASE NOISE IN A COMMUNICATION SYSTEM

(71) Applicant: Sanjole Inc., Honolulu, HI (US)

(72) Inventors: Joseph M. Fala, Honolulu, HI (US); Hao Liu, Honolulu, HI (US)

(73) Assignee: Sanjole Inc., Honolulu, HI (US)

(21) Appl. No.: 16/946,957

(22) Filed: Jul. 13, 2020

Related U.S. Application Data
(60) Provisional application No. 62/873,797, filed on Jul. 12, 2019.

(51) Int. Cl. H03L 7/093; H03L 7/081; H04L 7/00; H04L 7/033

(52) U.S. Cl. CPC H03L 7/093; H04L 7/0331; H04L 7/0054; H03L 7/081

(57) ABSTRACT

A system, circuit and method for providing a controlled oscillator frequency with reduced phase noise for use in a communication system. In one embodiment, the circuit includes a delay line coupled to an output of a voltage controlled oscillator (“VCO”). The circuit also includes a combiner having a first input coupled to an output of the delay line, and a second input coupled to the output of the VCO. An output of the combiner is coupled to a control input of the VCO.

### TECHNICAL FIELD

The present disclosure is related to communication systems and, more particularly, to a system and method for correcting phase noise in a communication system.

### BACKGROUND

As cellular communication technology moves to higher carrier frequencies, such as Fifth Generation (“5G”) communication systems that employ carrier frequencies between about 20 and 50 gigahertz (“GHz”), there is a growing need to generate baseband and carrier signals with a single frequency with reduced phase noise (e.g., a “tone”). Current 4G and earlier communication systems employ carrier frequencies between two and six GHz that have less sensitivity to phase noise than higher frequency 5G communication systems. There is also substantial reliance in new communication systems such as 5G as well as earlier systems on orthogonal frequency division multiplexing (“OFDM”), which relies on the generation of signals with a specific frequency and manageable (e.g., minimal) phase noise for wideband communications.

The 5G communication systems generally employ OFDM and rely on a large number of spectral tones that should be separated from each other by, for instance, 15 kilohertz (“kHz”). The spectral tones should be mutually orthogonal, meaning one tone should not materially interfere with a neighboring tone. Thus, random phase noise can be a limiting factor in communication systems employing OFDM operating with high carrier frequencies such as those contemplated for use with 5G communication systems.

Cellular and other communication technologies typically employ a voltage controlled oscillator (“VCO”) that generates a sine wave output with a frequency locked to a multiple of a frequency of an input frequency source, such as a signal generated by a crystal oscillator. The crystal oscillators are a frequent choice to generate a low-frequency sine wave at a controllable frequency by employing mechanical resonance and a piezoelectric effect in the crystal.

For example, a crystal frequency of 100 megahertz (“MHz”) for a VCO that produces a 10 GHz output signal employs an upscaling of frequency by a factor of 100. The result is that any phase noise of the crystal is also upscaled by the factor of 100. Accordingly, upscaled frequencies are very sensitive to phase noise. Sideband frequencies of concern are generally in the range of 10 kHz to 100 kHz.

The result is such crystal oscillators produce an unacceptably high level of random phase noise when the oscillator frequency is multiplied up by a large factor to produce a high carrier frequency. A high level of random phase noise is produced even when careful design techniques are employed such as enclosing portions of the circuit in a well shielded and temperature-controlled enclosure and regulating supply voltages for the oscillator itself.

Accordingly, what is needed in the art is a system and method for reducing the random phase noise that is produced employing design techniques in communication systems with higher carrier frequencies.

### SUMMARY

These and other problems are generally solved or circumvented, and technical advantages are generally achieved, by advantageous embodiments of the present invention for a system, circuit and method for providing a controlled oscillator frequency with reduced phase noise for use in a communication system. In one embodiment, the circuit includes a delay line coupled to an output of a voltage controlled oscillator (“VCO”). The circuit also includes a combiner having a first input coupled to an output of the delay line, and a second input coupled to the output of the VCO. An output of the combiner is coupled to a control input of the VCO.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, reference is now made to the following descriptions taken in conjunction with the accompanying drawings, in which:

FIGS. 1 to 3 illustrate diagrams of embodiments of a communication system and portions thereof;

FIGS. 4 to 6 illustrate graphical representations of embodiments of orthogonal frequency domain multiplexing (“OFDM”) carriers;

FIG. 7 illustrates a block diagram of an embodiment of a conditioning circuit coupled to a phase-locked loop;

FIGS. 8 and 9 illustrate graphical representations representing a frequency domain analysis of the effect of noise sources with respect to the conditioning circuit coupled to the phase-locked of FIG. 7;

FIG. 10 illustrates a block diagram of representations of a phase-locked loop and a phase-locked loop with a conditioning circuit;

FIG. 11 illustrates first and second Bode plots demonstrating feedback gain of a phase-locked loop and a phase-locked loop with the conditioning circuit;

FIG. 12 illustrates a layout diagram of an embodiment of a delay line;

FIGS. 13 and 14 illustrate block diagrams with accompanying Bode plots for different delays circuits;

FIG. 15 illustrates a block diagram of an embodiment of a conditioning circuit coupled to the phase-locked loop of FIG. 7;

FIG. 16 illustrates a graphical representation representing a frequency domain analysis of the effect of noise sources with respect to the conditioning circuit coupled to a phase-locked loop of FIG. 15; and

FIG. 17 illustrates a flow diagram of an embodiment of method of operating a conditioning circuit for use with a phase-locked loop including a voltage controlled oscillator (“VCO”).

Corresponding numerals and symbols in the different figures generally refer to corresponding parts unless otherwise indicated, and may not be redescribed in the interest of brevity after the first instance. The FIGUREs are drawn to illustrate the relevant aspects of exemplary embodiments.

### DETAILED DESCRIPTION

The making and using of the present exemplary embodiments are discussed in detail below. It should be appreciated, however, that the embodiments provide many applicable inventive concepts that can be embodied in a wide variety of specific contexts. The specific embodiments discussed are merely illustrative of specific ways to make and use the systems, subsystems, circuits and methods for providing a controlled oscillator frequency with reduced phase noise for use in a communication system. While the principles will be described in the environment of a Fifth Generation (“5G”) communication system, any system that would benefit from a low noise tone reference such as a Wi-Fi, WiMAX, router, personal computer, television receiver, military radar transceiver (any system which uses a low phase noise phase-lock loop or other circuit) is well within the broad scope of the present disclosure.

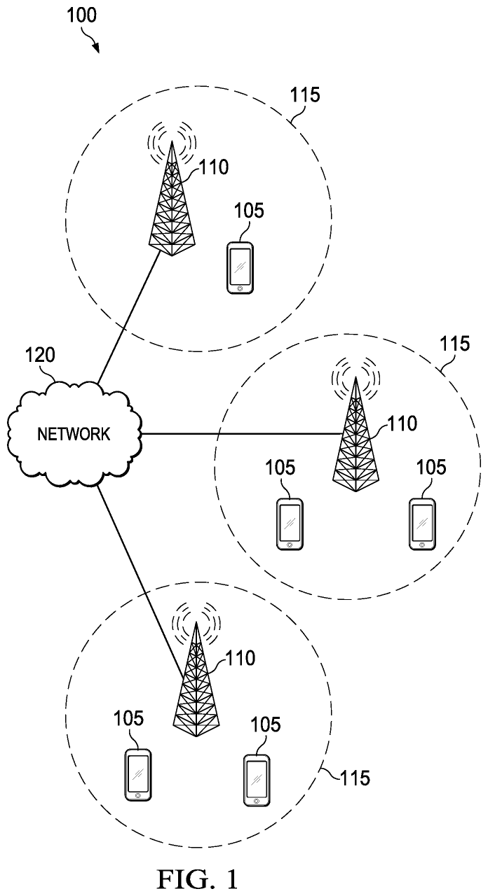

Referring initially to FIGS. 1 to 3, illustrated are diagrams of embodiments of a communication system 100, and portions thereof. As shown in FIG. 1, the communication system 100 includes one or more instances of user equipment (generally designated 105) in communication with one or more radio access nodes (generally designated 110). The communication network 100 is organized into cells 115 that are connected to a core network 120 via corresponding radio access nodes 110. In particular embodiments, the communication system 100 may be configured to operate according to specific standards or other types of predefined rules or procedures. Thus, particular embodiments of the communication system 100 may implement communication standards, such as Global System for Mobile Communications (“GSM”), Universal Mobile Telecommunications System (“UMTS”), Long Term Evolution (“LTE”), and/or other suitable 2G, 3G, 4G, or 5G standards; wireless local area network (“WLAN”) standards, such as the IEEE 802.11 standards; and/or any other appropriate wireless communication standard, such as the Worldwide Interoperability for Microwave Access (“WiMax”), Bluetooth, and/or ZigBee standards.

In addition to the devices mentioned above, the user equipment 105 may be a portable, pocket-storable, hand-held, computer-comprised, or vehicle-mounted mobile device, enabled to communicate voice and/or data, via a wireless or wireline connection. A user equipment 105 may have functionality for performing monitoring, controlling, measuring, recording, etc., that can be embedded in and/or controlled/monitored by a processor, central processing unit (“CPU”), microprocessor, application-specific integrated circuits (“ASICs”), or the like, and configured for connection to a network such as a local ad-hoc network or the Internet. The user equipment 105 may have a passive communication interface, such as a quick response (Q) code, a radio-frequency identification (“RFID”) tag, a near field communication (“NFC”) tag, or the like, or an active communication interface, such as a modem, a transceiver, a transmitter-receiver, or the like. In an Internet of Things (“IoT”) scenario, the user equipment 105 may include sensors, metering devices such as power meters, industrial machinery, or home or personal appliances (e.g., refrigerators, televisions, personal wearables such as watches) capable of monitoring and/or reporting on its operational status or other functions associated with its operation.

Alternative embodiments of the user equipment 105 may include additional components beyond those shown in FIG. 1 that may be responsible for providing certain aspects of the functionality, including any of the functionality described herein and/or any functionality necessary to support the solution described herein. As just one example, the user equipment 105 may include input interfaces, devices and circuits, and output interfaces, devices and circuits. The input interfaces, devices, and circuits are configured to allow input of information into the user equipment 105, and are connected to a processor to process the input information. For example, input interfaces, devices, and circuits may include a microphone, a proximity or other sensor, keys/buttons, a touch display, one or more cameras, a universal serial bus (“USB”) port, or other input elements. Output interfaces, devices, and circuits are configured to allow output of information from the user equipment 105, and are connected to the processor to output information from the user equipment 105. For example, output interfaces, devices, or circuits may include a speaker, a display, vibrating circuitry, a USB port, a headphone interface, or other output elements. Using one or more input and output interfaces, devices, and circuits, the user equipment 105 may communicate with end users and/or the wireless network, and allow them to benefit from the functionality described herein.

As another example, the user equipment 105 may include a power source. The power source may include power management circuitry. The power source may receive power from a power supply, which may either be internal or external to the power source. For example, the user equipment 105 may include a power supply in the form of a battery or battery pack that is connected to, or integrated into, the power source. Other types of power sources, such as photovoltaic devices, may also be used. As a further example, the user equipment 105 may be connectable to an external power supply (such as an electricity outlet) via an input circuitry or interface such as an electrical cable, whereby the external power supply supplies power to the power source.

The radio access nodes 110 such as base stations are capable of communicating with the user equipment 105 along with any additional elements suitable to support communication between user equipment 105 or between a user equipment 105 and another communication device (such as a landline telephone). The radio access nodes 110 may be categorized based on the amount of coverage they provide (or, stated differently, their transmit power level) and may then also be referred to as femto base stations, pico base stations, micro base stations, or macro base stations. The radio access nodes 110 may also include one or more (or all) parts of a distributed radio access node such as centralized digital units and/or remote radio units (“RRUs”), sometimes referred to as remote radio heads (“RRHs”). Such remote radio units may or may not be integrated with an antenna as an antenna integrated radio. Parts of a distributed radio base stations may also be referred to as nodes in a distributed antenna system (“DAS”). As a particular non-limiting example, a base station may be a relay node or a relay donor node controlling a relay.

The radio access nodes 110 may be composed of multiple physically separate components (e.g., a NodeB component and a radio network controller (“RNC”) component, a base transceiver station (“BTS”) component and a base station controller (“BSC”) component, etc.), which may each have their own respective processor, memory, and interface components. In certain scenarios in which the radio access nodes 110 include multiple separate components (e.g., BTS and BSC components), one or more of the separate components may be shared among several network nodes. For example, a single RNC may control multiple NodeBs. In such a scenario, each unique NodeB and BSC pair, may be a separate network node. In some embodiments, the radio access nodes 110 may be configured to support multiple radio access technologies (“RATs”). In such embodiments, some components may be duplicated (e.g., separate memory for the different RATs) and some components may be reused (e.g., the same antenna may be shared by the RATs).

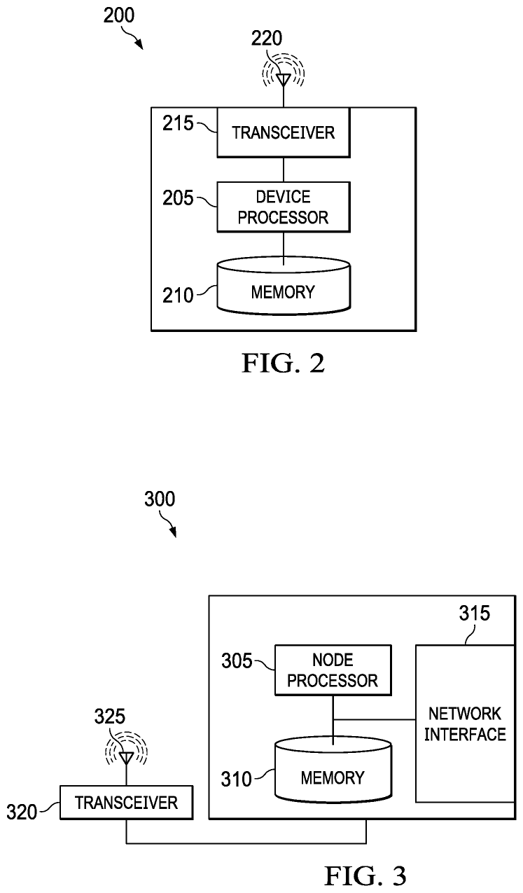

Although the illustrated user equipment 105 may represent communication devices that include any suitable combination of hardware and/or software, the user equipment 105 may, in particular embodiments, represent devices such as the example user equipment 200 illustrated in greater detail by FIG. 2. Similarly, although the illustrated radio access node 110 may represent network nodes that include any suitable combination of hardware and/or software, these nodes may, in particular embodiments, represent devices such as the example radio access node 300 illustrated in greater detail by FIG. 3.

As shown in FIG. 2, the example user equipment 200 includes a processor (or processing circuitry) 205, a memory 210, a transceiver 215 and antennas 220. In particular embodiments, some or all of the functionality described above as being provided by machine type communication (“MTC”) and machine-to-machine (“M2M”) devices, and/or any other types of communication devices may be provided by the device processor 205 executing instructions stored on a computer-readable medium, such as the memory 210 shown in FIG. 2. Alternative embodiments of the user equipment 200 may include additional components (such as the interfaces, devices and circuits mentioned above) beyond those shown in FIG. 2 that may be responsible for providing certain aspects of the device's functionality, including any of the functionality described above and/or any functionality necessary to support the solution described herein.

As shown in FIG. 3, the example radio access node 300 includes a processor (or processing circuitry) 305, a memory 310, a transceiver 320, a network interface 315 and antennas 325. In particular embodiments, some or all of the functionality described herein may be provided by a base station, a radio network controller, a relay station and/or any other type of network nodes (see examples above) in connection with the node processor 305 executing instructions stored on a computer-readable medium, such as the memory 310 shown in FIG. 3. Alternative embodiments of the radio access node 300 may include additional components responsible for providing additional functionality, including any of the functionality identified above and/or any functionality necessary to support the solution described herein.

The processors, which may be implemented with one or a plurality of processing devices, performs functions associated with its operation including, without limitation, precoding of antenna gain/phase parameters, encoding and decoding of individual bits forming a communication message, formatting of information and overall control of a respective communication device. Exemplary functions related to management of communication resources include, without limitation, hardware installation, traffic management, performance data analysis, configuration management, security, billing, location analysis and the like. The processors may be of any type suitable to the local application environment, and may include one or more of general-purpose computers, special purpose computers, microprocessors, digital signal processors (“DSPs”), field-programmable gate arrays (“FPGAs”), application-specific integrated circuits (“ASICs”), and processors based on a multi-core processor architecture, as non-limiting examples.

The processors may include one or more of radio frequency (“RF”) transceiver circuitry, baseband processing circuitry, and application processing circuitry. In some embodiments, the RF transceiver circuitry, baseband processing circuitry, and application processing circuitry may be on separate chipsets. In alternative embodiments, part or all of the baseband processing circuitry and application processing circuitry may be combined into one chipset, and the RF transceiver circuitry may be on a separate chipset. In still alternative embodiments, part or all of the RF transceiver circuitry and baseband processing circuitry may be on the same chipset, and the application processing circuitry may be on a separate chipset. In yet other alternative embodiments, part or all of the RF transceiver circuitry, baseband processing circuitry, and application processing circuitry may be combined in the same chipset.

The processors may be configured to perform any determining operations described herein. Determining as performed by the processors may include processing information obtained by the processor by, for example, converting the obtained information into other information, comparing the obtained information or converted information to information stored in the respective device, and/or performing one or more operations based on the obtained information or converted information, and as a result of the processing making a determination.

The memories may be one or more memories and of any type suitable to the local application environment, and may be implemented using any suitable volatile or nonvolatile data storage technology such as a semiconductor-based memory device, a magnetic memory device and system, an optical memory device and system, fixed memory and removable memory. The programs stored in the memories may include program instructions or computer program code that, when executed by an associated processor, enable the respective communication device to perform its intended tasks. Of course, the memories may form a data buffer for data transmitted to and from the same. Exemplary embodiments of the system, subsystems, and modules as described herein may be implemented, at least in part, by computer software executable by processors, or by hardware, or by combinations thereof.

The transceivers modulate information onto a carrier waveform for transmission by the respective communication device via the respective antenna(s) to another communication device. The respective transceiver demodulates information received via the antenna(s) for further processing by other communication devices. The transceiver is capable of supporting duplex operation for the respective communication device. The network interface performs similar functions as the transceiver communicating with a core network.

The antennas may be any type of antenna capable of transmitting and receiving data and/or signals wirelessly. In some embodiments, the antennas may include one or more omni-directional, sector or panel antennas operable to transmit/receive radio signals between, for example, two gigahertz (“GHz”) and 66 GHz. An omni-directional antenna may be used to transmit/receive radio signals in any direction, a sector antenna may be used to transmit/receive radio signals from devices within a particular area, and a panel antenna may be a line of sight antenna used to transmit/receive radio signals in a relatively straight line.

A basis of advanced communication systems such as those described herein generally entails creating pure carrier tones with reduced or minimal phase error (e.g., phase wobble or phase noise). Such tones can be created digitally and are generally modulated with data for communication to a remote module. These tones are substantially shifted up in frequency from that of an input frequency source, such as a signal with a frequency generated by a crystal-controlled oscillator, to the higher frequencies of a carrier channel.

It is not practical in an ordinary communication system to create a pure, nearly perfect tone of a single frequency without random phase errors such as that produced by an atomically controlled oscillator. When a tone is shifted up in frequency, phase errors are magnified which interferes with detection and demodulation of a received signal. In practice, a “pure” tone is created digitally at a low, baseband frequency that can span a range of frequencies that is often 100 megahertz (“MHz”) wide. When a baseband signal is scaled up, for example, to 20 to 40 gigahertz (“GHz”) employing, for instance, a mixer or combiner, phase distortion of the up-scaled signal is substantially compromised. The resulting 20 or 40 GHz tone and all its associated sideband tones exhibit substantial random sideband noise with superimposed random sideband components.

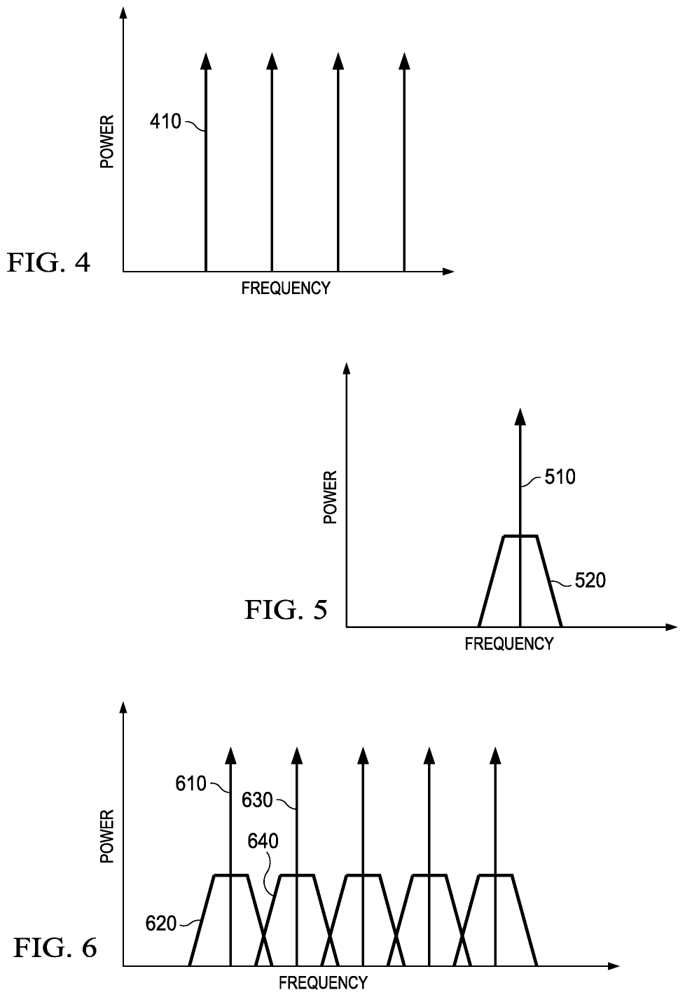

Referring now to FIGS. 4 to 6, illustrated are graphical representations of embodiments of orthogonal frequency domain multiplexing (“OFDM”) carriers. FIG. 4 illustrates vertical lines representing a plurality of pure-tone OFDM carriers (one of which is designated 410). The vertical lines represent pure tones with no phase noise. FIG. 5 illustrates the output of a local oscillator with phase noise 520 superimposed on an OFDM carrier 510. The carriers (e.g., first and second carriers 610, 630) illustrated in FIG. 6 are the output of a local oscillator with corresponding phase noise (e.g., first and second phase noise 620, 640). As is evident in FIG. 6, the first phase noise 620 of the first carrier 610 overlaps the second phase noise 640 of the second carrier 630, which can produce a decoding error in a receiver employing OFDM signaling.

Operation of wireless and Ethernet routers, radio access nodes as well as user equipment in general is thus dependent on creating quality tones such as near-perfect, pure tones for a transmitted signal for substantially error-free communication. The highly competitive markets in which such products are offered request a low-cost arrangement to create near-perfect tones for a transmitted signal.

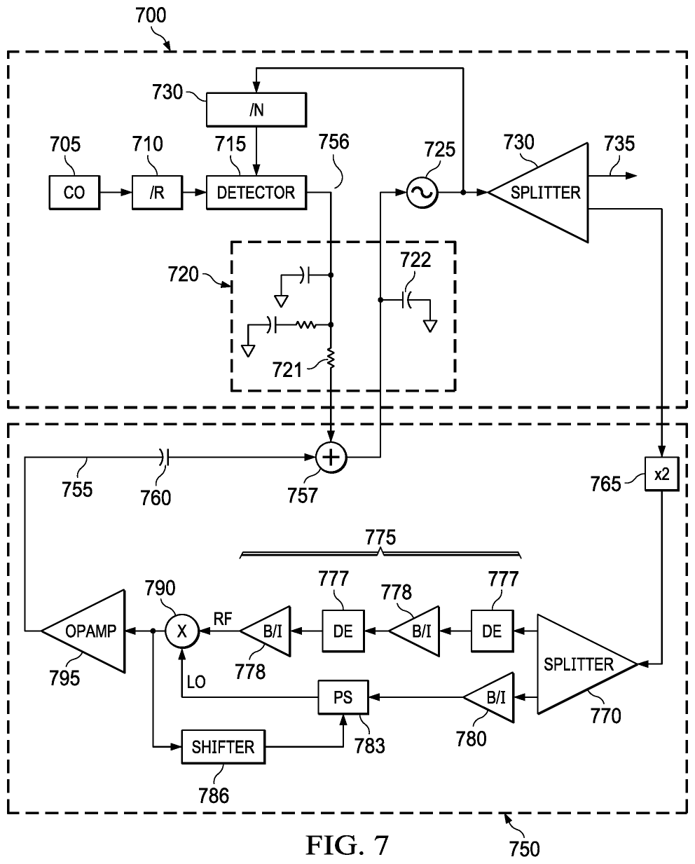

Referring now to FIG. 7, illustrated is a block diagram of an embodiment of a conditioning circuit (also referred to as a “circuit”) 750 coupled to a phase-locked loop 700. A crystal oscillator (designated “CO”) 705 produces a signal with an accurate, known frequency employing resonant mechanical vibrations of a piezoelectric crystal as an input of a frequency divider 710. The output signal produced by frequency divider 710 has a frequency that is the frequency of the crystal oscillator 705 divided by an integer such as by the integer “R” illustrated in FIG. 7. The signal produced by frequency divider 710 is coupled to an input of a frequency-phase detector (also referred to as a “detector”) 715. The output of the detector 715 is coupled to a low-pass filter 720. The low-pass filter 720 illustrated in FIG. 7 is formed with two poles and a zero (in the sense of the complex frequency domain) provided by the resistance and capacitors included therein.

An output of the low-pass filter 720 that controls the frequency of a voltage controlled oscillator (“VCO”) 725 and at low frequencies (e.g., less than roughly 10 kHz) is coupled to a control input of the VCO 725. An output signal produced by the VCO 725 is coupled to frequency divider 730 that produces another input for the detector 715, i.e., the frequency of the VCO 725 divided by a rational number, such as the rational number “N” illustrated in FIG. 7. As a result, the detector 715 produces a signal for a feedback loop (or path) that controls the frequency of the VCO 725 that is a measure of a phase difference between the divided output frequency of the VCO 725 and the divided frequency of the crystal oscillator 705. The result enables the feedback loop to control the frequency of the VCO 725 to be N/R times the frequency of the crystal oscillator 705.

The circuit 750 provides a feedback path (or loop) 755 to control the frequency of the VCO 725, the function of which is to reduce phase jitter produced by the VCO 725. The feedback path 755 of the circuit 750 corrects the phase of high frequencies, and the feedback path 756 of the phase-locked loop 700 corrects the phase of low frequencies.

An output signal produced by the VCO 725 is coupled to a signal splitter 730, the output 735 of which is an output of the phase-locked loop 700. The output signal produced by signal splitter 730 is fed to an input of the circuit 750. The input to the circuit 750 is coupled to a frequency multiplier (e.g., a frequency doubler) 765. Frequency doubler and other frequency multipliers (or dividers by operation of multiplying by a fraction) are contemplated within the broad scope of the present invention. An output of frequency doubler 765 is coupled to a signal splitter 770, one output of which is coupled to a delay line 775. In the example illustrated in FIG. 7, the delay line 775 is formed with a two nanosecond (“ns”) delay element (generally designated 777) coupled to buffer/isolator (generally designated 778), an output of which is coupled to another two ns delay element 777, an output of which is coupled to another buffer/isolator 778. An output of the delay line 775 produces a delay signal coupled to a combiner 790. The combiner 790 may include a mixer and/or a high speed phase detector. In the frequency domain, a mixer is a well-known circuit element, and performs addition and subtraction of frequencies.

The frequency doubler 765 is included to increase the gain of the frequency and phase correction process. The output of frequency doubler 765 is roughly a sine wave, and can be omitted by increasing the delay of the delay line 775. Other multiplying coefficients including fractional numbers are contemplated within the broad scope of the present disclosure. The frequency doubler 765 provides 6 decibel (“dB”) gain at radio frequencies with less noise, where phase error becomes more obvious. While the terms frequency multiplier and frequency divider have been used herein, it should be understood that multiplying by a fraction performs a divider function and dividing by a fraction performs a multiplication function.

Another output of the signal splitter 770 is coupled to a buffer/isolator 780. An output of the buffer/isolator 780 is coupled to another input of the combiner 790 via a phase shifter (“PS”) 783. To null the output of the combiner 790 when the output of delay line 775 matches the phase of the signal produced by the signal splitter 770 without delay, the phase shifter 783 is included to provide an adjustment of the phase of the signal produced by the signal splitter 770. A “one-time” shift block (also referred to as a “shifter”) 786 is included to enable this adjustment. The “one-time” shift block 786 is formed with a one-time shift microprocessor configured to adjust phase near zero degrees (“°”) (or near 180° for a negative clarity input).

The output of combiner 790 produces a combined signal fed to an operational amplifier 795. An output of operational amplifier 795 is added by the feedback path 755 to the control input of VCO 725. The outputs of the two feedback loops are added/summed together in an arrangement that can cross over without mutual interference. As illustrated in FIG. 7, an adder/subtractor 757 sums (or subtracts) the signal (e.g., voltage signal or current signal) produced at the right terminal of resistor 721 on the feedback path 756 with the combined signal (e.g., voltage signal or current signal) produced on the feedback path 755. The summed signal (which, of course, may provide a negative result) is coupled to capacitor 722 and to the input control terminal of VCO 725. A capacitor 760 in the feedback path 755 blocks a dc component of the output of the operational amplifier 795. The feedback path 755 mitigates high-frequency noise at frequencies greater than, for instance, roughly 10 kHz.

The combined signal from the combiner 790 is a phase error signal due to phase noise produced by the VCO 725. An output of combiner 790 is added back into the input of the VCO 725 to reduce phase noise. The combiner 790 senses a difference between the output of the VCO 725 and a delayed copy (the delay signal) of the output of the VCO 725. In this arrangement, the higher the output frequency of the VCO 725 the better it can operate with the circuit 750, particularly when substantial delay is provided by the delay line 775.

The circuit 750 is included because an OFDM signal created by upscaling an oscillator output frequency inherently includes random phase noise that is superimposed on the resulting upscaled oscillator output frequency. As described herein, the higher the upscaling factor, the greater the resulting phase noise. The up-scaled phase noise in decibels is 20*log 10 of the up-scaling factor. The improved arrangement of the circuit 750 produces a low level of phase noise with a high upscaling factor.

The delay line 775 can be used to estimate a level of phase noise. In such an estimation process, a frequency discriminator estimates phase noise by comparing a signal with a delayed version of the signal. As introduced herein, a process to reduce phase noise employs a delayed version of a VCO 725 output signal in a feedback loop that employs a combiner 790 to compare the delayed VCO output signal, an “historical version” of the VCO output signal, with the VCO output signal not delayed. Thus, the process corrects phase and frequency errors of the VCO 725 employing VCO signals that are delayed and not delayed. Different VCO frequencies can employ different nominal delays that are nulled out using the adjustable phase shifter 783 for a frequency of interest.

Thus, a circuit 750 for use with a phase-locked loop 700 having a VCO 725 includes a delay line 775 coupled to an output of the VCO 725 and a combiner 790 having a first input coupled to an output of the delay line 775, a second input coupled to the output of the VCO 725, and an output coupled to a control input of the VCO 725. The delay line 775 may include a plurality of delay elements 777. The delay line 775 may include at least one of an electrically conductive delay element, an acoustic delay element, a photonic delay element, a quantum delay element, a magnetic delay element and a bandpass filter. In an embodiment, the delay of the delay line 775 is 24 ns produced by one cable delay in conjunction with a single amplifier. The combiner 790 is configured to perform a nonlinear (or linear) operation by forming a product of the first input of the combiner 790 and the second input of the combiner 790 to produce said output thereof. In an embodiment, the combiner (mixer) 790 can be constructed with an active or a passive mixer. A passive mixer (such as, for example, a ZX05-153MH mixer from Mini-Circuits of Brooklyn, N.Y.) can exhibit advantageous noise characteristics.

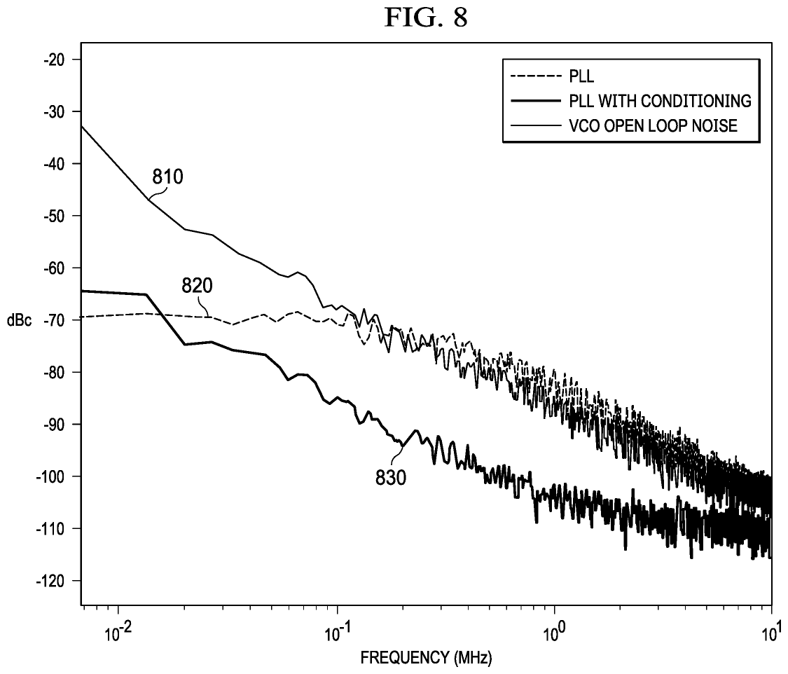

Turning now to FIG. 8, illustrated is a graphical representation representing a frequency domain analysis of the effect of noise sources with respect to the conditioning circuit coupled to a phase-locked loop of FIG. 7. The graphical representation of the VCO noise amplitude versus frequency in the frequency domain illustrates an open-loop VCO noise plot 810, a normal PLL noise plot 820, and a PLL noise plot with conditioning 830. The VCO frequency is represented on a logarithmic scale on the horizontal axis and noise amplitude is represented on a dBc scale on the vertical axis. A dBc scale is a decibel scale referenced to a carrier signal. The lower limit of frequency offset on the horizontal axis is 10 kHz. The open-loop VCO noise plot 810 represents a modeled reference noise level. The normal PLL noise plot 820 and the PLL noise plot with conditioning 830 represent frequency substantially locked to a crystal frequency along the horizontal portion, and the knee of the plot is where the phase-locked feedback loop stops following the reference crystal oscillator frequency. The PLL noise plot with conditioning 830 provides a plot with reduced noise as compared to the normal PLL noise plot 820. The PLL noise plot with conditioning 830 shows about 20 dB of improvement of phase noise relative to the normal PLL noise plot 820.

The resolution bandwidth (“RBW”) is ten kHz. Normalization is accomplished by subtracting 10*log₁₀ (RBW) or 40 dB from the y-axis. One subtracts 40 dB from the y-axis to normalize the graphs to one Hz. As illustrated in FIG. 8, VCO noise amplitude goes flat versus frequency at lower frequencies when the VCO frequency is controlled with a feedback loop, either with or without conditioning. FIG. 8 also shows that PLL noise with conditioning provides about 20 dB of noise improvement over a wide range of frequencies compared to a normal PLL, i.e., a PLL without conditioning.

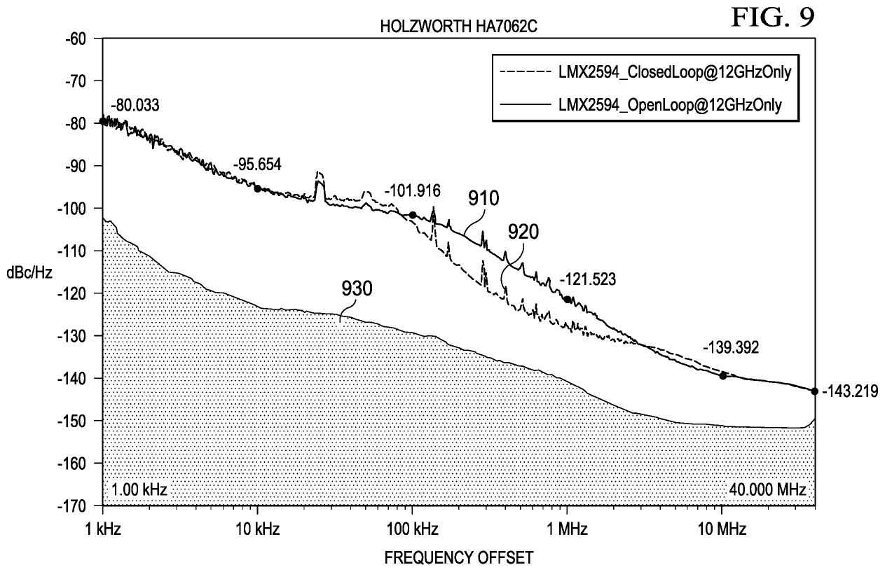

Turning now to FIG. 9, illustrated is a graphical representation of a frequency domain of the effect of noise sources with respect to a conditioning circuit coupled to the phase-locked loop analogous to FIG. 7. The curves illustrated in FIG. 9 represent results produced by an implementation formed with a passive 24 ns delay line. The graphical representation of the VCO noise amplitude versus frequency in the frequency domain illustrates a normal PLL noise plot 910 and a PLL noise plot with conditioning 920. The VCO frequency is represented on a logarithmic scale on the horizontal axis and noise amplitude is represented on a dBc/Hz scale on the vertical axis. A dBc/Hz scale is a decibel scale referenced to a carrier signal with resolution bandwidth normalized to 1 Hz. The lower limit of frequency offset shown on the horizontal axis is 1 kHz. The noise sensitivity plot 930 illustrates the noise sensitivity of the measurement device.

The normal PLL noise plot 910 and the PLL noise plot with conditioning 920 represent frequency substantially locked to a crystal frequency along the horizontal portion, and the knee of the plot is where the phase-locked feedback loop stops following the reference crystal oscillator frequency. The PLL noise plot with conditioning 920 provides reduced noise over a range of millimeter-wavelength frequencies of interest for 5G cellphone communication as compared to the normal PLL noise plot 910. The PLL noise plot with conditioning 920 shows about 12 dB of improvement of phase noise relative to the normal PLL noise plot 910. The measurement equipment employed to produce the plots illustrated on FIG. 9 is a Holzworth Instrumentation HA7062C Real-Time Phase Noise Analyzer.

The resolution bandwidth (“RBW”) is already normalized to 1 Hz. As illustrated in FIG. 9, VCO noise amplitude goes flat versus frequency at lower frequencies when the VCO frequency is controlled with a feedback loop, either with or without conditioning. FIG. 9 also shows that PLL noise with conditioning 920 provides about 12 dB of noise improvement over a wide range of frequencies compared to the normal PLL noise plot 910. Table I provides example parameters for the noise plots.

TABLE I

| Parameters | Value | |
|---|---|---|
| Measurement Name | LMX2594_OpenLoop@12 GHx | |
| Measurement Type | Absolute | |
| Measurement Time | 1.074 | seconds |
| DUT Frequency | 12 | GHz |
| DUT Power | 10.610 dBm (decibels | |
| | referenced to 1 mWatt) | |
| Jitter Start | 1 | kHz |
| Jitter Stop | 10 | MHz |
| RMS Noise | 4.715e−01° | |
| RMS Jitter | 109.153 | fs |

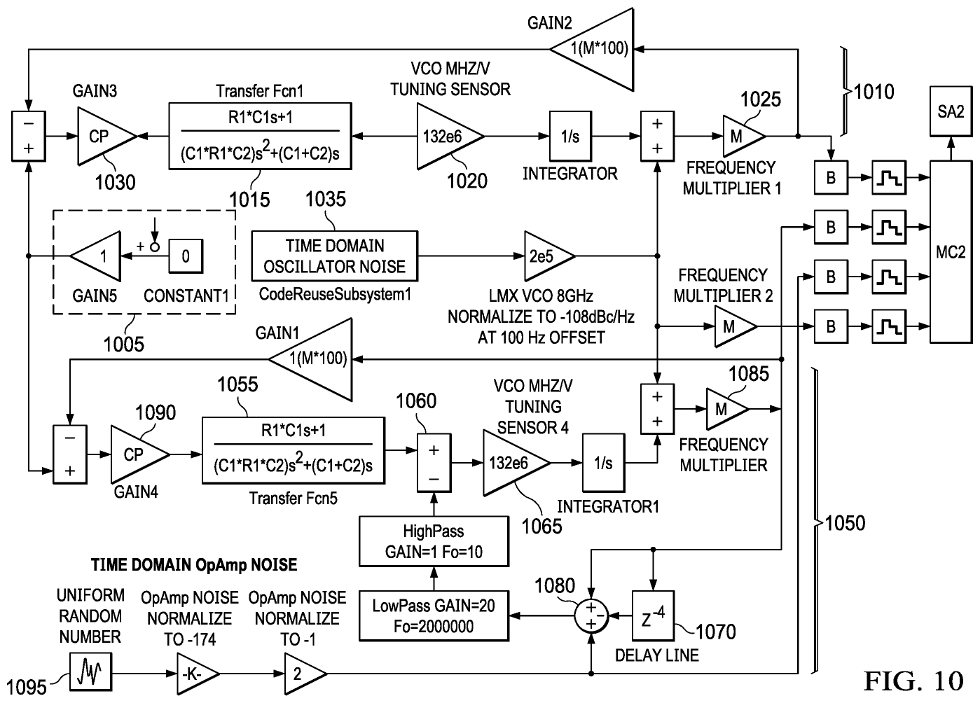

Turning now to FIG. 10, illustrated is a block diagram of representations of a phase-locked loop 1010 and a phase-locked loop with a conditioning circuit 1050. A baseband signal frequency source 1005 to the phase-locked loop 1010 and the phase-locked loop with the conditioning circuit 1050 is represented by a Constant1 and Gain5. Transfer functions 1015, 1055 for the phase-locked loop 1010 and the phase-locked loop with the conditioning circuit 1050, respectively, represent the low-pass filter 720 of FIG. 7. An adder/subtractor 1060 sums (or subtracts) the output of the feedback loops from the phase-locked loop with the conditioning circuit 1050. The phase-locked loop 1010 and the phase-locked loop with the conditioning circuit 1050 also include a VCO 1020, 1065, respectively. The phase-locked loop with the conditioning circuit 1050 includes a delay line 1070, which provides an input to a combiner 1080 along with the output from the phase-locked loop 1010. The phase-locked loop 1010 and the phase-locked loop with the conditioning circuit 1050 also include frequency multipliers 1025, 1085, respectively, each with a frequency-multiplying coefficient of two.

The values of capacitors and resistors in the low-pass filter 720 shown in FIG. 7 is represented by the transfer functions 1015, 1055 in FIG. 10, and are as follows:

C1=47e-6

R1=60

C2=0.1e-7

C3=1e-15

R3=50

The gains of charge pumps (“CP”) 1030, 1090 of the phase-locked loop 1010 and the phase-locked loop with the conditioning circuit 1050, respectively, are 0.005. Noise sources 1035, 1095 represent phase noise being interjected into the respective systems.

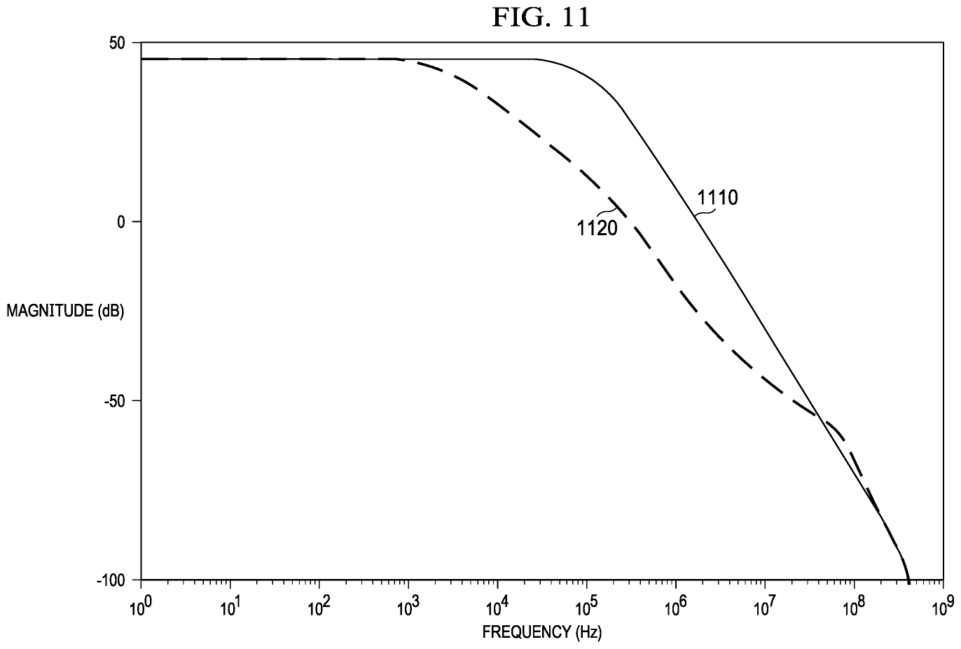

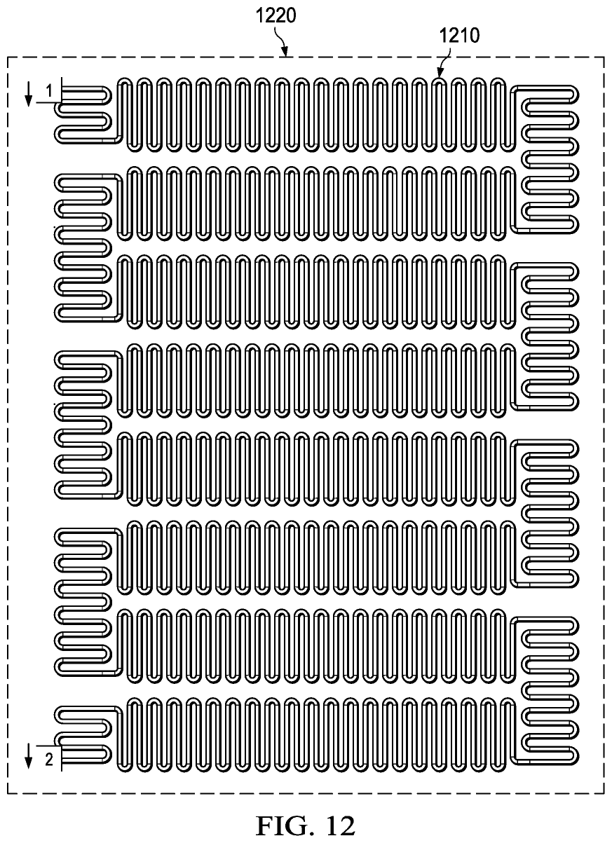

Turning now to FIG. 11, illustrated are first and second Bode plots 1110, 1120 demonstrating feedback gain of a phase-locked loop and a phase-locked loop with the conditioning circuit, respectively. The improvement or reduction in phase noise by up to, for instance, 30 dB is evident with the conditioning circuit. The first Bode plot 1110 illustrates gain versus frequency for a conventional phase-locked loop, and the second Bode plot 1120 illustrates gain versus frequency for a phase-locked loop with the conditioning circuit. The first and second Bode plots 1110, 1120 illustrate stability of the phase-locked loop, showing no “bump” in gain that would indicate an unwanted interaction or a mutual interference generated by summing of the conditioning circuit with the feedback loop of the phase-locked loop (e.g., at one kilohertz (“kHz”)).

Turning now to FIG. 12, illustrated is a layout diagram of an embodiment of a delay line. To produce a two nanosecond (“ns”) delay, the length of the conductive delay line circuit trace 1210 would be about one foot when a dielectric with an enhanced dielectric constant is formed below the conductive circuit trace of the delay line. The delay line illustrated in FIG. 12 is formed with a four mil-wide trace, with a five mil gap between adjacent strands of the conductive circuit trace. The height of the substrate 1220 is 2.8 mills and the dielectric constant in the delay line is 3.2. A loss tangent of 0.005 can be achieved with the indicated structure. Examples of physical processes that can be employed to implement a delay line include, without limitation, acoustic, electrical, and/or photonic components.

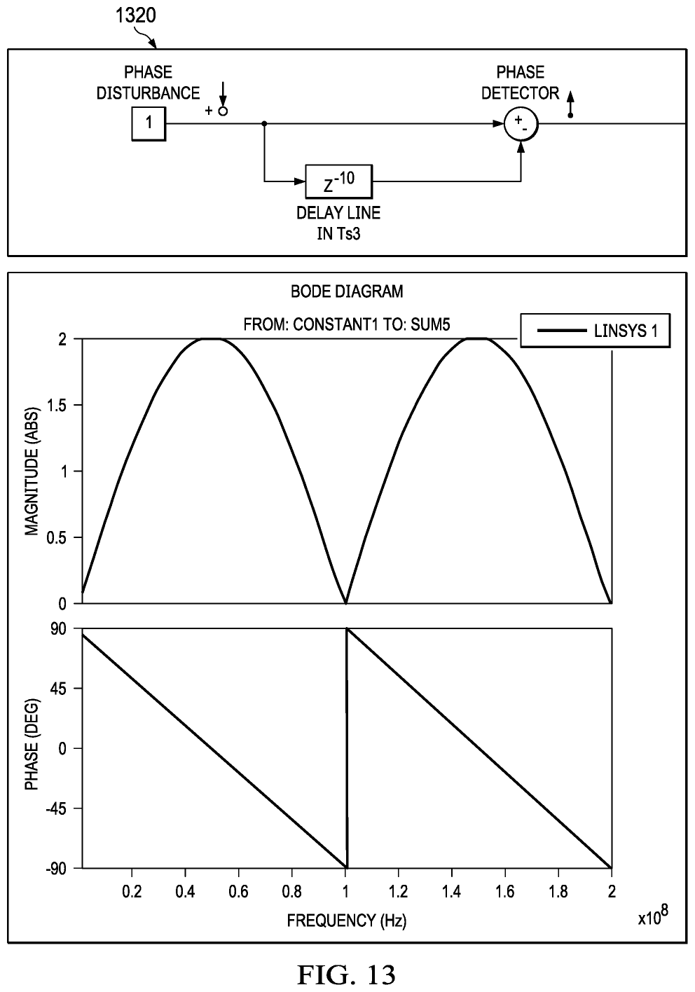

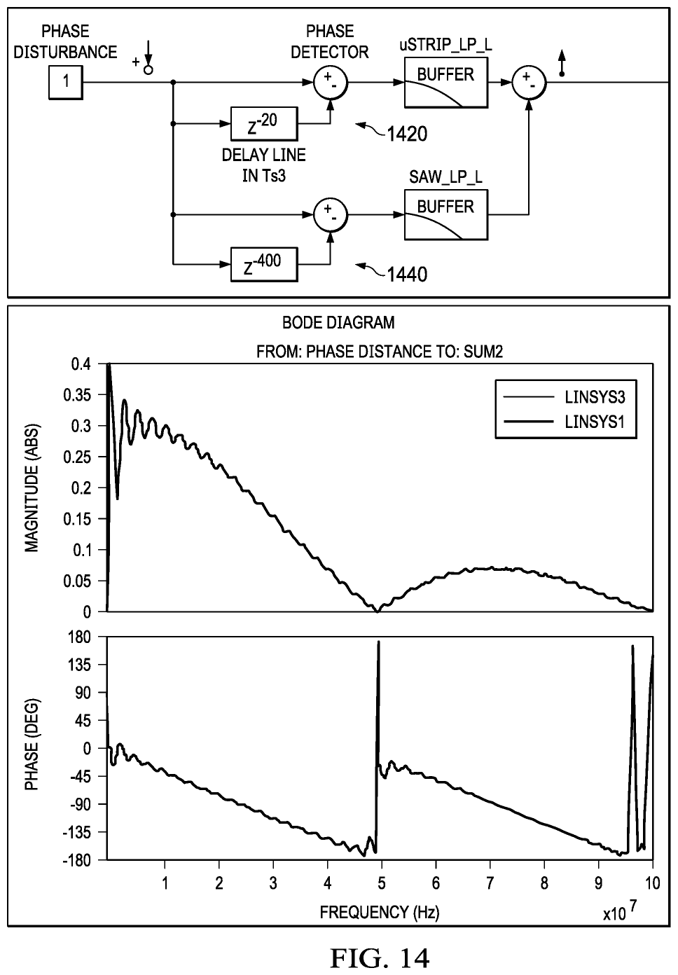

Turning now to FIGS. 13 and 14, illustrated are block diagrams with accompanying Bode plots for different delays circuits. FIG. 13 illustrates a block diagram with accompanying Bode plot representing a single delay line 1320. FIG. 14 illustrates a block diagram with accompanying Bode plot representing a first delay line 1420 and a second delay line 1440. The outputs of the two delay lines 1420, 1440 are added/summed together in an arrangement that can cross over without mutual interference. There are a few reasons for using a dual delay approach. First, it is advantageous to employ surface acoustical wave (“SAW”) delay lines because of their small size and large delay times, typically hundreds of nanoseconds to a few microseconds, but these delay lines typically operate at lower frequencies (below three GHz) both of which translate into lower gain. Note that the effective maximum gain of the delay line is proportional to freq*delay. For example, using an operating frequency “F1” with delay line length of “L1” versus an operating frequency “F2” with a delay line length of “L2”, the effective gain of the delay line is increased by (F1*L1)/(F2*L2) times or (20*log 10 (F1/F2)+20*log 10(L1/L2)) dB.)

Second, one can look at a simplified model of phase sensing for a phase noise signal compared to a 10 nanosecond (“ns”) delayed copy of the same phase noise signal. The phase sensor with a single delay line 1320 has a frequency response as shown in FIG. 13, and a phase sensor with a dual delay line 1420, 1440 has frequency response as shown in FIG. 14. Note that the system provides a maximum magnitude response at phase disturbance frequency of ½*1/delay or 50 MHz. It is also noted that the magnitude response is zero at 1/delay or 100 MHz, and also at zero Hz.

Since the magnitude is proportional to the gain of the noise cancellation, it would be beneficial to have a longer delay to permit a higher gain at low frequencies. Of particular interest is the range 10-70 kHz where most communication transmission systems demand low phase noise. While a longer delay, for example 400 ns, would help noise cancellation in this range, the longer frequency response of the delay would only be unstable at higher frequencies above 1/400 ns/2=˜1 MHz. This instability would far outweigh the benefit of 10-70 kHz cancellation.

A solution is use two delay lines 1420, 1440, one delay line for low frequencies and one delay line for high frequencies. The delay lines 1420, 1440 are then joined with a crossover circuit. By joining/summing those two delay line together, the benefit of the high gain of the longer delay line at lower frequency is utilized together with the benefit of high gain of the shorter delay line at lower frequency, of which the overall benefit is the effective gain is high over a much wider range of frequency. Lowpass filters on each of the delay lines 1420, 1440 are utilized to ensure gain stability beyond the frequency (½)*(1/shorter delay line delay time).

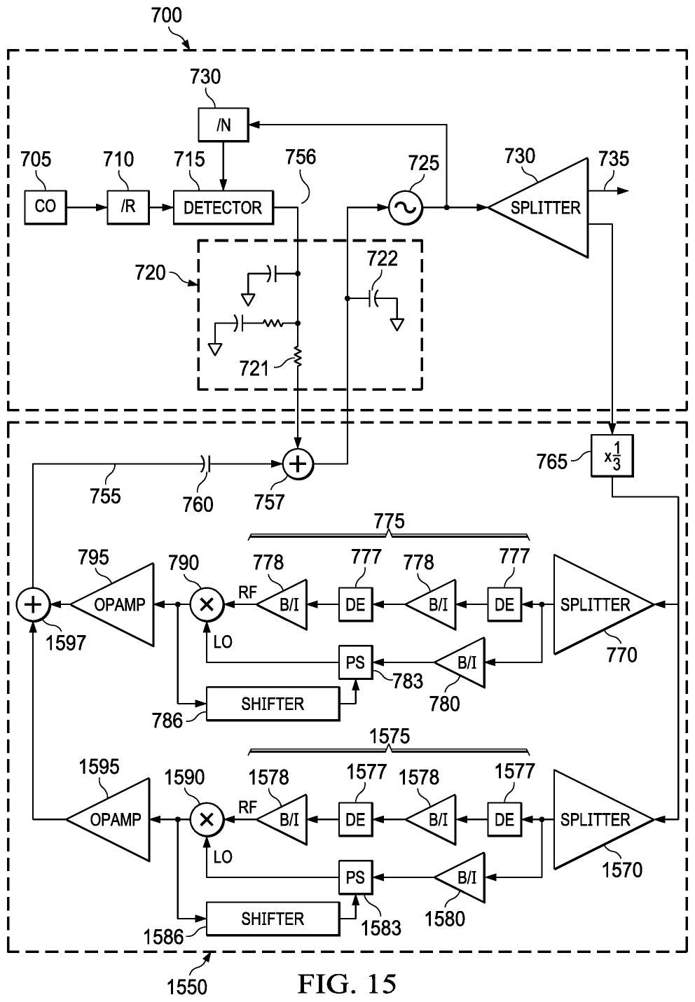

Referring now to FIG. 15, illustrated is a block diagram of an embodiment of a conditioning circuit (also referred to as a “circuit”) 1550 coupled to the phase-locked loop 700 of FIG. 7. A crystal oscillator (designated “CO”) 705 produces a signal with an accurate, known frequency employing resonant mechanical vibrations of a piezoelectric crystal as an input of a frequency divider 710. The output signal produced by frequency divider 710 has a frequency that is the frequency of the crystal oscillator 705 divided by an integer such as by the integer “R” illustrated in FIGS. 7 and 15. The signal produced by frequency divider 710 is coupled to an input of a frequency-phase detector (also referred to as a “detector”) 715. The output of the detector 715 is coupled to a low-pass filter 720. The low-pass filter 720 illustrated in FIGS. 7 and 15 is formed with two poles and a zero (in the sense of the complex frequency domain) provided by the resistance and capacitors included therein.

An output of the low-pass filter 720 that controls the frequency of a voltage controlled oscillator (“VCO”) 725 and at low frequencies (e.g., less than roughly 10 kHz) is coupled to a control input of the VCO 725. An output signal produced by the VCO 725 is coupled to frequency divider 730 that produces another input for the detector 715, i.e., the frequency of the VCO 725 divided by a rational number, such as the rational number “N” illustrated in FIGS. 7 and 15. As a result, the detector 715 produces a signal for a feedback loop (or path) that controls the frequency of the VCO 725 that is a measure of a phase difference between the divided output frequency of the VCO 725 and the divided frequency of the crystal oscillator 705. The result enables the feedback loop to control the frequency of the VCO 725 to be N/R times the frequency of the crystal oscillator 705.

The circuit 1550 provides a feedback path (or loop) 755 to control the frequency of the VCO 725, the function of which is to reduce phase jitter produced by the VCO 725. The feedback path 755 of the circuit 1550 corrects the phase of high frequencies, and the feedback path 756 of the phase-locked loop 700 corrects the phase of low frequencies.

An output signal produced by the VCO 725 is coupled to a signal splitter 730, the output 735 of which is an output of the phase-locked loop 700. The output signal produced by signal splitter 730 is fed to an input of the circuit 1550. The input to the circuit 1550 is coupled to a frequency multiplier (e.g., by a factor of one third in this case) 765. Frequency doublers and other frequency multipliers or dividers are contemplated within the broad scope of the present disclosure. An output of frequency multiplier 765 is coupled to a first signal splitter 770, one output of which is coupled to a first delay line 775. In the example illustrated in FIG. 15, the first delay line 775 is formed with a 20 nanosecond (“ns”) surface acoustical wave (“SAW”) first delay element (generally designated 777) coupled to a first buffer/isolator (generally designated 778), an output of which is coupled to another 20 ns delay element 777, an output of which is coupled to another first buffer/isolator 778. An output of the first delay line 775 produces a first delay signal coupled to a first combiner 790. The first combiner 790 may include a mixer and/or a high speed phase detector. In the frequency domain, a mixer is a well-known circuit element, and performs addition and subtraction of frequencies. The frequency multiplier 765 is included to reduce the frequency to acceptable for the SAW delay line technology used in 1550.

Another output of the first signal splitter 770 is coupled to a first buffer/isolator 780. An output of the first buffer/isolator 780 is coupled to another input of the first combiner 790 via a first phase shifter (“PS”) 783. To null the output of the first combiner 790 when the output of first delay line 775 matches the phase of the signal produced by the first signal splitter 770 without delay, the first phase shifter 783 is included to provide an adjustment of the phase of the signal produced by the first signal splitter 770. A “one-time” shift block (also referred to as a “first shifter”) 786 is included to enable this adjustment. The “one-time” shift block 786 is formed with a one-time shift microprocessor configured to adjust phase near zero degrees (“°”) (or near 180° for a negative clarity input). The output of first combiner 790 produces a combined signal fed to a first operational amplifier 795.

Again, the output signal produced by the VCO 725 is coupled to a signal splitter 730, the output 735 of which is an output of the phase-locked loop 700. The output signal produced by signal splitter 730 is fed to an input of the circuit 1550. The input to the circuit 550 is coupled to a frequency multiplier (e.g., by a factor of one third) 765. Frequency doublers and other frequency multipliers (or dividers by operation of multiplying by a fraction) are contemplated within the broad scope of the present disclosure. An output of frequency multiplier 765 is also coupled to a second signal splitter 1570, one output of which is coupled to a second delay line 1575. In the example illustrated in FIG. 15, the second delay line 1575 is formed with a 400 ns SAW second delay element (generally designated 1577) coupled to a second buffer/isolator (generally designated 1578), an output of which is coupled to another 400 ns delay element 1577, an output of which is coupled to another second buffer/isolator 1578. An output of the second delay line 1575 produces a second delay signal coupled to a second combiner 1590. The second combiner 1590 may include a mixer and/or a high speed phase detector. In the frequency domain, a mixer is a well-known circuit element, and performs addition and subtraction of frequencies. In an embodiment, the first and second combiners (mixers) 790, 1590 can be constructed with an active or a passive mixer. A passive mixer (such as, for example, a ZX05-153MH mixer from Mini-Circuits of Brooklyn, N.Y.) can exhibit advantageous noise characteristics. The frequency multiplier 765 used in 1550 is set to one third to lower the frequency within SAW delay line technology limits.

Another output of the second signal splitter 1570 is coupled to a second buffer/isolator 1580. An output of the second buffer/isolator 1580 is coupled to another input of the second combiner 1590 via a second phase shifter (“PS”) 1583. To null the output of the second combiner 1590 when the output of second delay line 1575 matches the phase of the signal produced by the second signal splitter 1570 without delay, the second phase shifter 1583 is included to provide an adjustment of the phase of the signal produced by the second signal splitter 1570. A “one-time” shift block (also referred to as a “second shifter”) 1586 is included to enable this adjustment. The “one-time” shift block 1586 is formed with a one-time shift microprocessor configured to adjust phase near zero degrees (“°”) (or near 180° for a negative clarity input). The output of second combiner 1590 produces a combined signal fed to a second operational amplifier 1595.

An output of first and second operational amplifiers 795, 1595 is fed to a crossover circuit 1597 for selection of the first and/or second delay signals, which is added by the feedback path 755 to the control input of VCO 725. The outputs of the two feedback loops are added/summed together in an arrangement that can cross over without mutual interference. As illustrated in FIG. 15, an adder/subtractor 757 sums (or subtracts) the signal (e.g., voltage signal or current signal) produced at the right terminal of resistor 721 on the feedback path 756 with the combined signal (e.g., voltage signal or current signal) produced on the feedback path 755. The summed signal (which, of course, may provide a negative result) is coupled to capacitor 722 and to the input control terminal of VCO 725. A capacitor 760 in the feedback path 755 blocks a dc component of the output of at least one of the first and second operational amplifiers 795, 1595 via the crossover switch 1597. The feedback path 755 mitigates high-frequency noise at frequencies greater than, for instance, roughly 10 kHz.

The combined signal from the first and/or second combiners 790, 1590 is a phase error signal due to phase noise produced by the VCO 725. An output of the first and/or second combiner 790, 1590 is added back into the input of the VCO 725 to reduce phase noise. The first and/or second combiner 790, 1590 senses a difference between the output of the VCO 725 and a delayed copy (the first and/or second delay signals) of the output of the VCO 725. In this arrangement, the large delay associated with delay lines 775, 1575 provides higher gain sensing of the phase difference between the output of the VCO 725 and the first and/or second delay lines 775, 1575. For example, using an operating frequency “F1” with delay line length of “L1” versus an operating frequency “F2” with a delay line length of “L2”, the effective gain of the delay line is increased by (F1*L1)/(F2*L2) times or (20*log 10(F1/F2)+20*log 10(L1/L2)) dB.

The circuit 1550 is included because an OFDM signal created by upscaling an oscillator output frequency inherently includes random phase noise that is superimposed on the resulting upscaled oscillator output frequency. As described hereinabove, the higher the upscaling factor, the greater the resulting phase noise. The improved arrangement of the circuit 1550 produces a low level of phase noise with a high upscaling factor.

The first and/or second delay lines 775, 1575 can be used to estimate a level of phase noise. In such an estimation process, a frequency discriminator estimates phase noise by comparing a signal with a delayed version of the signal. As introduced herein, a process to reduce phase noise employs a delayed version of a VCO 725 output signal in a feedback loop that employs a first and second combiner 790, 1590 to compare the delayed VCO output signal, an “historical version” of the VCO output signal, with the VCO output signal not delayed. Thus, the process corrects phase and frequency errors of the VCO 725 employing VCO signals that are delayed and not delayed. Different VCO frequencies can employ different nominal delays that are nulled out using the adjustable phase shifters 783, 1583 for a frequency of interest. While the circuits 750, 1550 of FIGS. 7 and 15 have been described in connection with a phase-lock loop 700, the circuits 750, 1550 are also applicable to other circuits subject to phase noise.

Thus, a circuit 1550 for use with a phase-locked loop 700 having a VCO 725 includes a first and second delay line 775, 1575 coupled to an output of the VCO 725 and a first and second combiner 790, 1590 having a first input coupled to an output of the first and second delay line 775, 1575, respectively, a second input coupled to the output of the VCO 725, and an output coupled to a control input of the VCO 725. The first and/or second delay lines 775, 1575 may include a plurality of delay elements 777, 1577, respectively. The first and/or second delay lines 775, 1575 may include at least one of an electrically conductive delay element, an acoustic delay element, a photonic delay element, a quantum delay element, a magnetic delay element and a bandpass filter. The first and/or second combiners 790, 1590 are configured to perform a nonlinear (or linear) operation by forming a product of the first input of the first and second combiners 790, 1590, respectively, and the second input of the first and second combiners 790, 1590, respectively, to produce said output thereof.

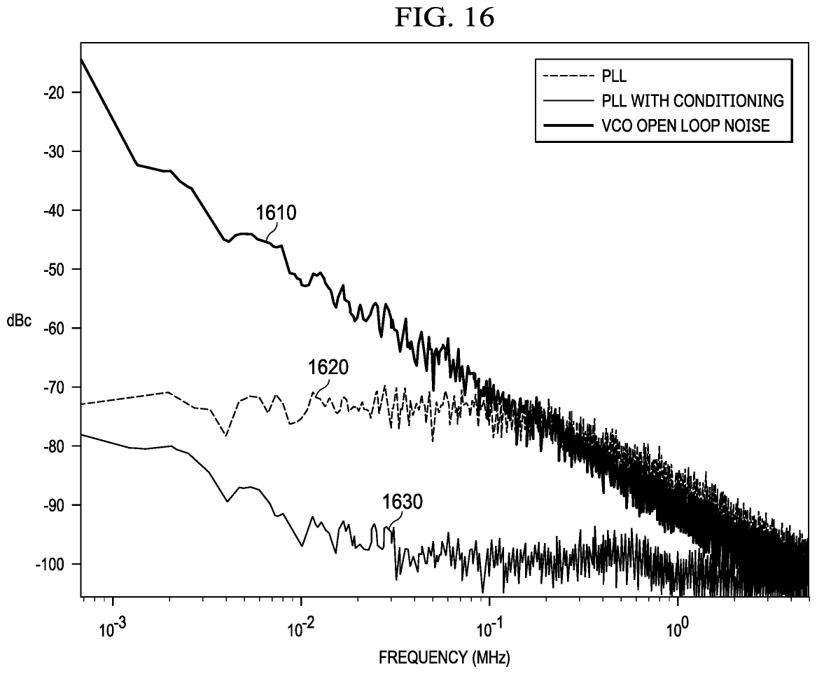

Turning now to FIG. 16, illustrated is a graphical representation representing a frequency domain analysis of the effect of noise sources with respect to the conditioning circuit coupled to a phase-locked loop of FIG. 15. The graphical representation of the VCO noise amplitude versus frequency in the frequency domain illustrates an open-loop VCO noise plot 1610, a normal PLL noise plot 1620, and a PLL noise plot with conditioning 1630. The VCO frequency is represented on a logarithmic scale on the horizontal axis and noise amplitude is represented on a dBc scale on the vertical axis. A dBc scale is a decibel scale referenced to a carrier signal. The lower limit of frequency offset on the horizontal axis is one kHz. The open-loop VCO noise plot 1610 represents a modeled reference noise level. The normal PLL noise plot 1620, and the PLL noise plot with conditioning 1630 represent frequency substantially locked to a crystal frequency along the horizontal portion, and the knee of the plot is where the phase-locked feedback loop stops following the reference crystal oscillator frequency. The PLL noise plot with conditioning 1630 provides a plot with reduced noise as compared to the lower than that of the normal PLL noise plot 1620. The PLL noise plot with conditioning 1630 shows about 20 dB of improvement of phase noise relative to the normal PLL noise plot 1620.

The resolution bandwidth (“RBW”) is one kHz. Normalization is accomplished by subtracting 10*log₁₀(RBW) or 30 dB from the y-axis. One subtracts 30 dB from the y-axis to normalize the graphs to one Hz. As illustrated in FIG. 16, VCO noise amplitude goes flat versus frequency at lower frequencies when the VCO frequency is controlled with a feedback loop, either with or without conditioning. FIG. 16 also shows that PLL noise with conditioning 1630 provides about 20 dB of noise improvement over a wide range of frequencies compared to a normal PLL noise plot 1620.

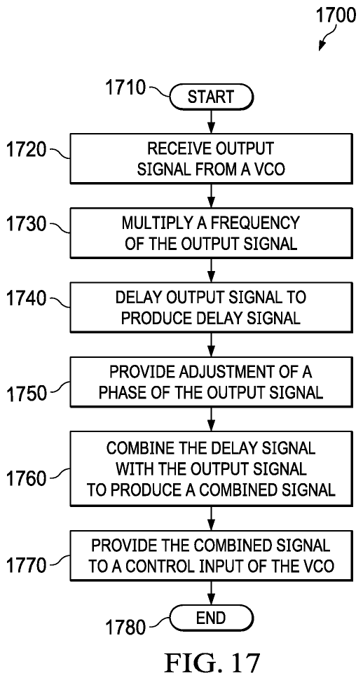

Turning now to FIG. 17, illustrated is a flow diagram of an embodiment of method 1700 of operating a conditioning circuit (also referred to as a “circuit”) for use with a phase-locked loop including a VCO. The phase-locked loop includes a phase detector with a first input coupled to the output of the VCO and an oscillator including a piezoelectric crystal coupled to a second input of the phase detector. The control input of the VCO is further coupled to a low-pass filter with an input coupled to an output of the phase detector (see, e.g., FIGS. 7 and 15 above).

The method 1700 begins at a start step or module 1710 and, thereafter, the circuit receives an output signal from the VCO at a step or module 1720. At a step or module 1730, the circuit multiplies a frequency of the output signal (e.g., doubles the output signal). At a step or module 1740, the circuit delays the output signal to produce a delay signal. The delaying may be performed by a plurality of delay elements and/or a plurality of delay lines. The delaying may also be performed by at least one of an electrically conductive delay element, an acoustic delay element, a photonic delay element, a quantum delay element, a magnetic delay element and a bandpass filter.

At a step or module 1750, the circuit provides an adjustment of a phase associated with the output signal. At a step or module 1760, the circuit combines the delay signal with the output signal (e.g., with a phase adjustment) to produce a combined signal. In accordance therewith, the adjustment introduced above may null the combined signal when the phase of the output signal is temporally aligned with the delay signal. The combining may include forming a product of the delay signal and the output signal to produce the combined signal (e.g., via a non-linear operation). If there are multiple delay signals via separate delay lines, the combining includes combining the respective delay signals with the output signal from the VCO, and adding the signals together or selecting one of the delay signals to produce the combined signal (see, for instance, FIG. 15). At a step or module 1770, the circuit provides the combined signal to a control input of the VCO. In accordance therewith, the circuit may add a signal from the low-pass filter to the combined signal when providing the same to the VCO. The method thereafter ends at a step or module 1780.

With continuing reference to the aforementioned description and FIGUREs, a conditioning circuit (or circuit) 750, 1550 and related method 1700 have been introduced herein. In one embodiment, the circuit 750, 1550 is for use with a phase-locked loop 700 having a voltage-controlled oscillator (“VCO”) and includes a first delay line 775 coupled to an output of the VCO 725, and a first combiner 790 having a first input coupled to an output of the first delay line 775, a second input coupled to the output of the VCO 725, and an output coupled to a control input of the VCO 725.

The circuit 750, 1550 may also include a phase shifter 783 coupled between the output of the VCO 725 and the second input of the first combiner 790. The phase shifter 783 is configured to be adjusted to null the output of the first combiner 790 when a phase of the output of the VCO 725 is temporally aligned with the output of the first delay line 775.

The phase-locked loop 700 includes a phase detector 715 with a first input coupled to the output of the VCO 725 and an oscillator 705 including a piezoelectric crystal coupled to a second input of the phase detector 715. The control input of the VCO 725 is further coupled to a low-pass filter 720 with an input coupled to an output of the phase detector 715. The circuit 750, 1550 may also include an adder/subtractor 757 with a first input coupled to an output of the low-pass filter 720 and a second input coupled to the output of the first combiner 790, an output of the adder/subtractor 757 being coupled to the control input of the VCO 725.

The circuit 750, 1550 may also include a second delay line 1575 coupled to the output of the VCO 725, and a second combiner 1590 having a first input coupled to an output of the second delay line 1575, a second input coupled to the output of the VCO 725, and an output coupled to the control input of the VCO 725. The first delay line 775 and/or the second delay line 1575 may include a plurality of delay elements 777, 1577, respectively.

The circuit 750, 1550 may also include a frequency multiplier 765 coupled between the output of the VCO 725 and the first input and the second input of the first combiner 790. The first combiner 790 is configured to perform a nonlinear (or linear) operation by forming a product of the first input of the first combiner 790 and the second input of the first combiner 790 to produce the output thereof. The second combiner 1590 is also configured to perform a nonlinear (or linear) operation by forming a product of the first input of the second combiner 1590 and the second input of the second combiner 1590 to produce the output thereof.

The foregoing description of embodiments of the present proposed solution has been presented for the purpose of illustration and description. It is not intended to be exhaustive or to limit the proposed solution to the present form disclosed. Alternations, modifications and variations can be made without departing from the spirit and scope of the present proposed solution.

As described above, the exemplary embodiment provides both a method and corresponding apparatus consisting of various modules providing functionality for performing the steps of the method. The modules may be implemented as hardware (embodied in one or more chips including an integrated circuit such as an application specific integrated circuit), or may be implemented as software or firmware for execution by a processor. In particular, in the case of firmware or software, the exemplary embodiment can be provided as a computer program product including a computer readable storage medium embodying computer program code (i.e., software or firmware) thereon for execution by the computer processor. The computer readable storage medium may be non-transitory (e.g., magnetic disks; optical disks; read only memory; flash memory devices; phase-change memory) or transitory (e.g., electrical, optical, acoustical or other forms of propagated signals-such as carrier waves, infrared signals, digital signals, etc.). The coupling of a processor and other components is typically through one or more busses or bridges (also termed bus controllers). The storage device and signals carrying digital traffic respectively represent one or more non-transitory or transitory computer readable storage medium. Thus, the storage device of a given electronic device typically stores code and/or data for execution on the set of one or more processors of that electronic device such as a controller.

Although the embodiments and its advantages have been described in detail, it should be understood that various changes, substitutions, and alterations can be made herein without departing from the spirit and scope thereof as defined by the appended claims. For example, many of the features and functions discussed above can be implemented in software, hardware, or firmware, or a combination thereof. Also, many of the features, functions, and steps of operating the same may be reordered, omitted, added, etc., and still fall within the broad scope of the various embodiments.

Moreover, the scope of the various embodiments is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized as well. Accordingly, the appended claims are intended to include within their scope such processes, machines, manufacture, compositions of matter, means, methods, or steps.

What is claimed:

1. A circuit for use with a phase-locked loop including a voltage-controlled oscillator (VCO), comprising:
a first delay line coupled to an output of said VCO; and
a first combiner having a first input coupled to an output of said first delay line, a second input coupled to said output of said VCO, and an output coupled to a control input of said VCO.

2. The circuit as recited in claim 1 further comprising a phase shifter coupled between said output of said VCO and said second input of said first combiner.

3. The circuit as recited in claim 2 wherein said phase shifter is configured to be adjusted to null said output of said first combiner when a phase of said output of said VCO is temporally aligned with said output of said first delay line.

4. The circuit as recited in claim 1 wherein said phase-locked loop includes a phase detector with a first input coupled to said output of said VCO and an oscillator including a piezoelectric crystal coupled to a second input of said phase detector.

5. The circuit as recited in claim 4 wherein said control input of said VCO is further coupled to a low-pass filter with an input coupled to an output of said phase detector.

6. The circuit as recited in claim 5 further comprising an adder/subtractor with a first input coupled to an output of said low-pass filter and a second input coupled to said output of said first combiner, an output of said adder/subtractor being coupled to said control input of said VCO.

7. The circuit as recited in claim 1 further comprising a frequency multiplier coupled between said output of said VCO and said first input and said second input of said first combiner.

8. The circuit as recited in claim 1 wherein said first delay line comprises a plurality of delay elements.

9. The circuit as recited in claim 1, further comprising:
a second delay line coupled to said output of said VCO; and
a second combiner having a first input coupled to an output of said second delay line, a second input coupled to said output of said VCO , and an output coupled to said control input of said VCO.

10. The circuit as recited in claim 1 wherein said first combiner is configured to perform an operation by forming a product of said first input of said first combiner and said second input of said first combiner to produce said output thereof.

11. A method of operating a circuit for use with a phase-locked loop including a voltage-controlled oscillator (VCO), comprising:
receiving an output signal from said VCO;
delaying said output signal to produce a first delay signal;
combining said first delay signal with said output signal to produce a combined signal; and
providing said combined signal to a control input of said VCO.

12. The method as recited in claim 11 further comprising providing an adjustment of a phase associated with said output signal.

13. The method as recited in claim 12 wherein said providing said adjustment comprises nulling said combined signal when said phase of said output signal is temporally aligned with said first delay signal.

14. The method as recited in claim 11 wherein said phase-locked loop includes a phase detector with a first input coupled to said output of said VCO and an oscillator including a piezoelectric crystal coupled to a second input of said phase detector.

15. The methods recited in claim 14 wherein said control input of said VCO is further coupled to a low-pass filter with an input coupled to an output of said phase detector.

16. The method as recited in claim 15 wherein said providing comprises adding a signal from said low-pass filter with said combined signal.

17. The method as recited in claim 11 further comprising multiplying a frequency of said output signal.

18. The method as recited in claim 11 wherein said delaying is performed by a plurality of delay elements.

19. The method as recited in claim 11 wherein said delaying and said combining further comprises:
delaying said output signal to produce a second delay signal; and
combining said second delay signal with said output signal and selecting at least one of said first delay signal and said second delay signal to produce said combined signal.

20. The method as recited in claim 11 wherein said combining comprises forming a product of said first delay signal and said output signal to produce said combined signal.
